(19) United States
(12) Patent Application Publication
(10) Pub. No.: US 2026/0351293 A1
(43) Pub. Date: Nov. 5, 2026

(54) MEMORY CHIP HAVING HYBRID BONDING PADS AND SEMICONDUCTOR DEVICE INCLUDING THE SAME

(71) Applicant: AP MEMORY TECHNOLOGY CORPORATION, HSINCHU COUNTY (TW)

(72) Inventor: WENLIANG CHEN, HSINCHU COUNTY (TW)

(21) Appl. No.: 19/399,601

(22) Filed: Nov. 24, 2025

Related U.S. Application Data
(60) Provisional application No. 63/789,467, filed on Apr. 16, 2025.

(51) Int. Cl. G11C 5/06; G11C 5/10; G11C 11/4091; H10D 80/30

(52) U.S. Cl. CPC G11C 5/063; G11C 5/10; G11C 11/4091; H10D 80/30

(57) ABSTRACT

A memory chip includes a substrate and a plurality of memory array tiles (MATs). The plurality of MATs are disposed over the substrate. At least one MAT includes a sensing circuit, a memory array, and a plurality of first pads. From a top view of the memory chip, the sensing circuit is disposed in a first region. From the top view of the memory chip, the memory array is located in a second region adjacent to the first region, and is electrically coupled to the sensing circuit. From the top view of the memory chip, the plurality of first pads are disposed in the first region. The plurality of first pads are disposed over the sensing circuit. The plurality of first pads are electrically coupled to the sensing circuit, and are configured to provide output of the sensing circuit.

### PRIORITY CLAIM AND CROSS-REFERENCE

The present application claims priority to U.S. Provisional Patent Application No. 63/789,467, filed on Apr. 16, 2025, which is incorporated by reference herein in its entirety.

### BACKGROUND

The present disclosure relates to a memory devices and a semiconductor device, and more particularly, to a memory device having hybrid bonding pads and a semiconductor device including the same.

High-speed computing and artificial intelligence (AI) require memory architectures that can support massive data throughput with low latency and high energy efficiency. As a result, the memory subsystem has become a critical bottleneck in achieving the full potential of high-speed computing and AI systems. Traditionally, static random-access memory (SRAM) has been the preferred choice for on-chip caches and embedded memory due to its fast access times and ease of integration with logic circuits. However, the continuous scaling of SRAM has encountered significant challenges, making it increasingly difficult to meet the growing demands of larger and faster memory arrays. SRAM is also costly due to its complex memory cells. In contrast, dynamic random-access memory (DRAM) offers inherently higher density, lower area per bit, and reduced cost compared to SRAM, prompting the consideration of DRAM as a viable alternative for embedded memory.

### SUMMARY

Some embodiments of the present disclosure provide a memory chip. The memory chip includes a substrate and a plurality of memory array tiles (MATs). The plurality of MATs are disposed over the substrate. At least one MAT of the plurality of MATs includes a sensing circuit, a memory array, and a plurality of first pads. From a top view of the memory chip, the sensing circuit is disposed in a first region. From the top view of the memory chip, the memory array is disposed in a second region adjacent to the first region, and is electrically coupled to the sensing circuit. From the top view of the memory chip, the plurality of first pads are disposed in the first region. The plurality of first pads are disposed over the sensing circuit. The plurality of first pads are electrically coupled to the sensing circuit, and are configured to provide output of the sensing circuit.

Some embodiments of the present disclosure provide a semiconductor device. The semiconductor device include a memory chip and a logic chip. The memory chip includes a substrate and a plurality of MATs disposed over the substrate of the memory chip. At least one MAT of the plurality of MATs includes a sensing circuit, a memory array electrically coupled to the sensing circuit, and a plurality of first pads electrically coupled to the sensing circuit and configured to provide output of the sensing circuit. The logic chip includes a substrate and a plurality of fourth pads. From a side view of the logic chip, the plurality of fourth pads are disposed over the substrate of the logic chip. The plurality of first pads of the at least one MAT are directly coupled to the plurality of fourth pads of the logic chip.

The memory chip and the semiconductor device disclosed in the present disclosure are suitable for high speed computing. The access time, power consumption, and bandwidth of the memory chip, which may include DRAM cells, are comparable to the SRAM.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a side view of a semiconductor device according to some comparative embodiments of the present disclosure.

FIG. 2 is a functional block diagram of a memory block of the memory chip of FIG. 1, according to some comparative embodiments of the present disclosure.

FIG. 3 is a functional block diagram of a semiconductor device according to some comparative embodiments of the present disclosure.

FIG. 4 is a functional block diagram of a memory block of the memory chip of FIG. 3, according to some comparative embodiments of the present disclosure.

FIG. 5 is a functional block diagram of a semiconductor device according to some embodiments of the present disclosure.

FIG. 6A is a top view of a memory block of the memory chip of FIG. 5, according to some embodiments of the present disclosure.

FIG. 6B is a circuit schematic of a memory array, according to some embodiments of the present disclosure.

FIG. 7 is a side view of a memory array tile (MAT) along a line of FIG. 6, according to some embodiments of the present disclosure.

FIG. 8 is a side view of the MAT along another line of FIG. 6, according to some embodiments of the present disclosure.

FIG. 9 is a side view of the MAT along yet another line of FIG. 6, according to some embodiments of the present disclosure.

FIG. 10 is a side view of the semiconductor device according to some embodiments of the present disclosure.

FIG. 11 is a side view of the semiconductor device according to some embodiments of the present disclosure.

FIG. 12 is a functional block diagram illustrating a row formed by MATs, according to some embodiments of the present disclosure.

FIG. 13 is a circuit schematic of the MAT according to some embodiments of the present disclosure.

FIG. 14 is a circuit schematic of a column selection unit according to some embodiments of the present disclosure.

FIG. 15 is a circuit schematic illustrating the connection configuration of the column selection unit between two MATs, according to some embodiments of the presents disclosure.

FIG. 16 is a top view of the MAT according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “top”, “bottom”, “front”, “back”, “left”, “right”, “horizontal”, “vertical” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It will be understood that when an element is referred to as being “connected to” or “coupled to” another element, it may be directly connected to or coupled to the other element, or intervening elements may be present.

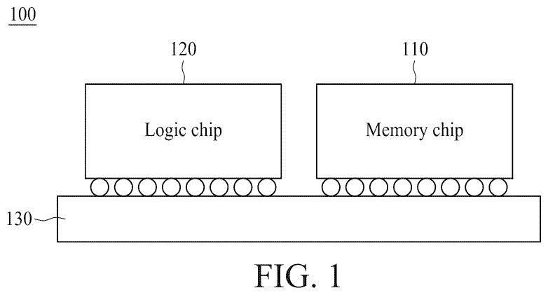

FIG. 1 is a side view of a semiconductor device 100 according to some comparative embodiments of the present disclosure. The semiconductor device 100 includes a memory chip 110, a logic chip 120, and a package substrate 130 (e.g., a printed circuit board). The memory chip 110 and the logic chip 120 are electrically coupled to the package substrate 130, thereby achieving communication through the substrate 130. The memory chip 110 may include logic circuits (not shown) that can control the operation of the memory chip 110. In some embodiments, the memory chip 110 includes one or more memory blocks, such as the dynamic random-access memory (DRAM) blocks.

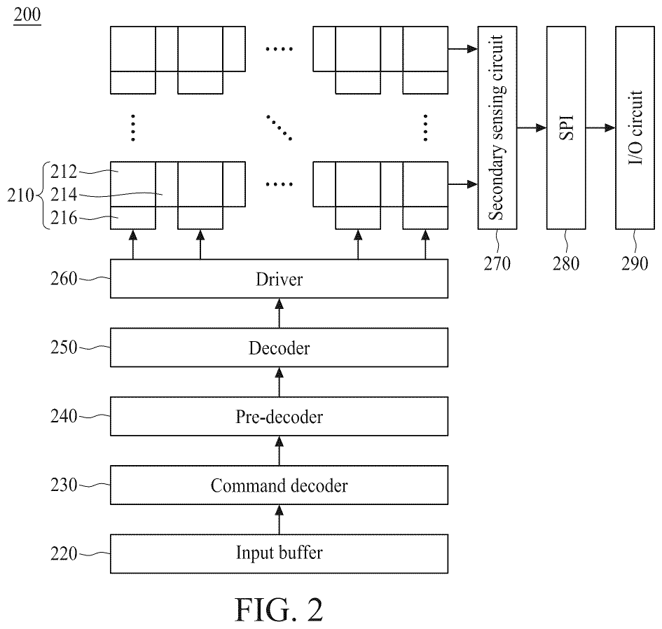

FIG. 2 is a functional block diagram of a memory block 200 of the memory chip 110 of FIG. 1, according to some comparative embodiments of the present disclosure. The memory block 200 includes a plurality of memory array tiles (MATs) 210. The MAT 210 includes a memory array 212 (e.g., a DRAM memory array), a sensing circuit 214, and a driving circuit 216. The memory array 212 may include a plurality of word lines, a plurality of bit lines, and a plurality of memory cells disposed at intersections of the word line and the bit lines. The sensing circuit 214 can amplify the small voltage differences on the bit lines of the memory array 212 during a read operation. The driving circuit 216 can provide the necessary current and voltage levels to activate the word lines of the memory array 212 to select the specific row. The memory block 200 further includes peripheral circuits disposed in the vicinity of the MATs 210, including an input buffer 220, a command decoder 230, a pre-decoder 240, a decoder 250, a driver 260, a secondary sensing circuit 270, a serial peripheral interface (SPI) 280, and an input/output (I/O) circuit 290.

The input buffer 220 can receive address signals and control signals from the logic chip 120, and can ensure that the address signals and the control signals are stable and at the correct voltage levels before providing them to the command decoder 230. The command decoder 230 can interpret control signals (such as row address strobe (RAS), column address strobe (CAS), write enable (WE), and output enable (OE)) and generate internal control signals to manage read, write, refresh, and other operations. The pre-decoder 240 can break down the address bits into smaller groups and partially decode them, with the output of the pre-decoder 240 being supplied to the decoder 250. This improves speed and reduces power consumption of the decoder 250. The decoder 250 can translate binary address inputs into a one-hot global enable signal. The driver 260 can buffer and distribute the one-hot global enable signal to a specific MAT 210 to activate the driving circuit 216 of the specific MAT 210. The secondary sensing circuit 270 receives output of the sensing circuit 214 through global data lines (not shown), and can further amplify the output of the sensing circuit 214.

However, due to the 2D configuration of the memory chip 110, all I/O pins of the memory chip 110 are arranged around its edges. The number of I/O pins is limited by the edge length of the memory chip 110. Therefore, the low number of I/O output pins restrict the bandwidth of the memory chip 110. Additionally, the extensive peripheral circuits of the memory chip 110 as well as the long resistance-capacitance (RC) traces within these peripheral circuits consume considerable power and cause significant signal latency. Due to the strong demand for high-throughput, low-latency data processing in applications such as high-speed computing and AI systems, vertical stacked (3D-stacked) memory architecture has become the prevailing industry trend. Vertical stacking allows through-silicon vias (TSVs) or other vertical interconnects, enabling more interconnects per unit area and higher bandwidth. Moreover, vertical stacking allows signals travel shorter distances vertically, thereby reducing latency and power consumption.

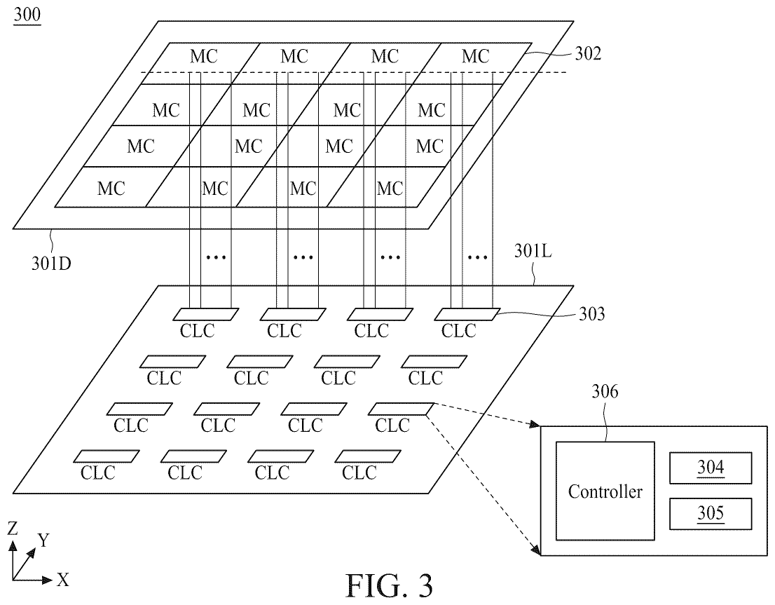

FIG. 3 is a functional block diagram of a semiconductor device 300 according to some comparative embodiments of the present disclosure. The semiconductor device 300 can be implemented using 3D-stacked memory architecture. A wafer 301D and a wafer 301L of the semiconductor device 300 can be stacked one above the other by using hybrid bonding process or other applicable process. Each memory chip 302 (denoted as “MC” in FIG. 3) formed on the wafer 301D can be implemented as a DRAM chip. The logic chips 303 (denoted as “CLC” in FIG. 3), formed on the substrate 301L, are configured to control operation of the memory chips 302, respectively. In the present embodiment, each logic chip 303 may include, but is not limited to, an input buffer 304, a command decoder 305, and a controller 306. The input buffer 304 and the command decoder 305 of FIG. 3 are similar to the input buffer 220 and the command decoder 230 of FIG. 2, respectively; their detailed descriptions are therefore omitted. The controller 306 can control operation of the memory chip 302, the input buffer 304, and the command decoder 305.

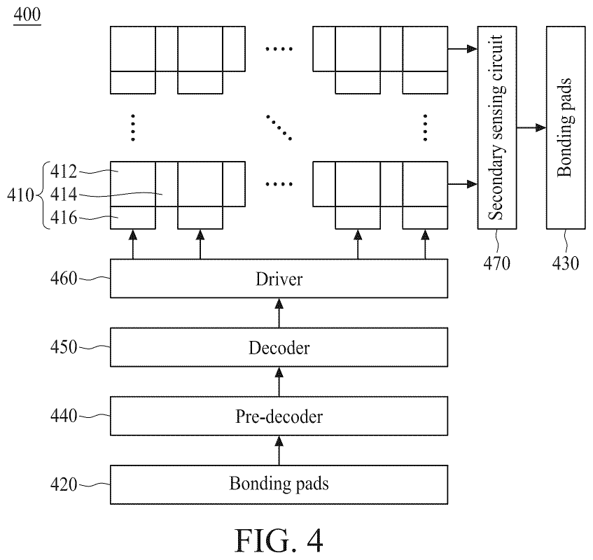

FIG. 4 is a functional block diagram of a memory block 400 of the memory chip 302 of FIG. 3, according to some comparative embodiments of the present disclosure. Each memory chips 302 includes one or more memory blocks 400. The memory block 400 includes a plurality of MATs 410, a plurality of bonding pads 420, a plurality of bonding pads 430, a pre-decoder 440, a decoder 450, a driver 460, and a secondary sensing amplifier 470. The MAT 410 includes a memory array 412 (e.g., a DRAM memory array), a sensing circuit 414, and a driving circuit 416. The MAT 410, the pre-decoder 440, the decoder 450, the driver 460, and the secondary sensing amplifier 470 of FIG. 4 are similar to the MAT 210, the pre-decoder 240, the decoder 250, the driver 260, and the secondary sensing circuit 270 of FIG. 2, respectively; their detailed descriptions are therefore omitted.

The bonding pads 420 and the bonding pads 430 are electrically connected to the logic chip 303. The bonding pads 420 can receive address signals and the control signals from the command decoder 305 of the logic chip 303. The bonding pads 430 can supply the output of the secondary sensing amplifier 470 to the controller 309 of the logic chip 303. The number of bonding pads 420 may range from several tens to several hundreds, and the same applies to the bonding pads 430. Accordingly, compared with the memory block 200, the bandwidth of the memory block 400 is enhanced. In addition, since the input buffer 304 and the command decoder 305 are moved to the logic chip 303, the power consumption and signal latency of the memory block 400 are reduced in some extent.

However, the memory chip 302 continues to include a substantial number of peripheral circuits, resulting in considerable power consumption. In addition, given that the bonding pads 420 and 430 are disposed at a distance from the MATs 410, there remains potential for improvements in signal latency. Accordingly, in order to achieve the objective of replacing SRAM with DRAM, a more compact 3D-stacked DRAM architecture is necessary.

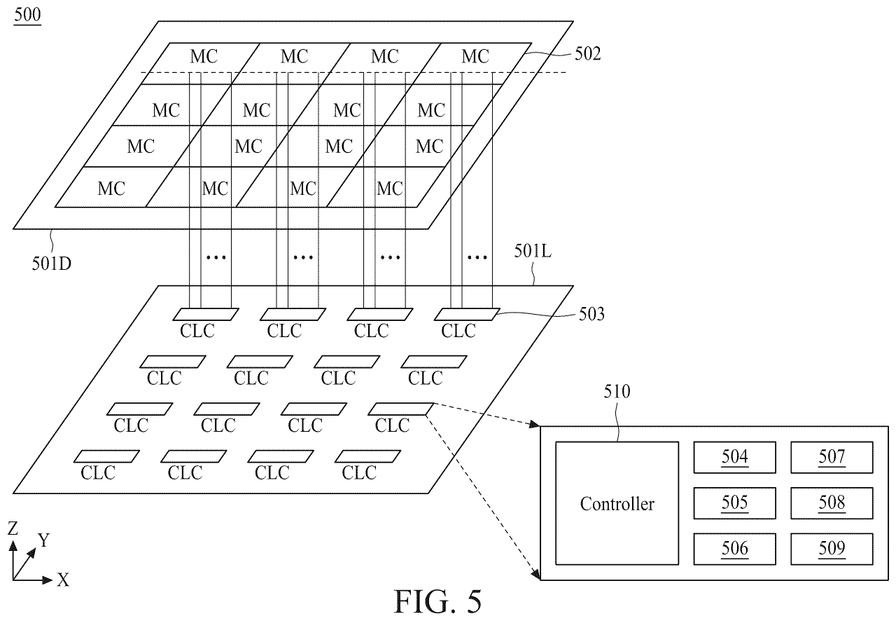

FIG. 5 is a functional block diagram of a semiconductor device 500 according to some embodiments of the present disclosure. The semiconductor device 500 can be implemented using 3D-stacked memory architecture. A wafer 501D and a wafer 501L of the semiconductor device 500 can be stacked one above the other by using hybrid bonding process or other applicable process. Each memory chip 502 (denoted as “MC” in FIG. 5) formed on the wafer 501D can be implemented as a DRAM chip. The logic chips 503 (denoted as “CLC” in FIG. 5), formed on the substrate 501L, are configured to control operation of the memory chips 502, respectively. In the present embodiment, each logic chip 503 may include, but is not limited to, an input buffer 504, a command decoder 505, a pre-decoder 506, a decoder 507, a driver 508, and a secondary sensing circuit 509, which are similar to the input buffer 220, the command decoder 230, the pre-decoder 240, the decoder 250, the driver 260, and the secondary sensing circuit 270 of FIG. 2, respectively; their detailed descriptions are therefore omitted. The logic chip 503 may further include a controller 510. The controller 51 can control operation of the memory chip 502, the input buffer 504, the command decoder 505, the pre-decoder 506, the decoder 507, the driver 508, and the secondary sensing circuit 509.

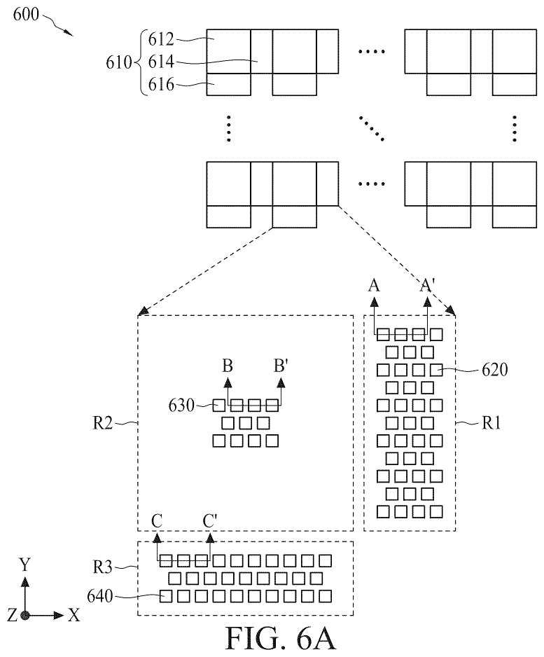

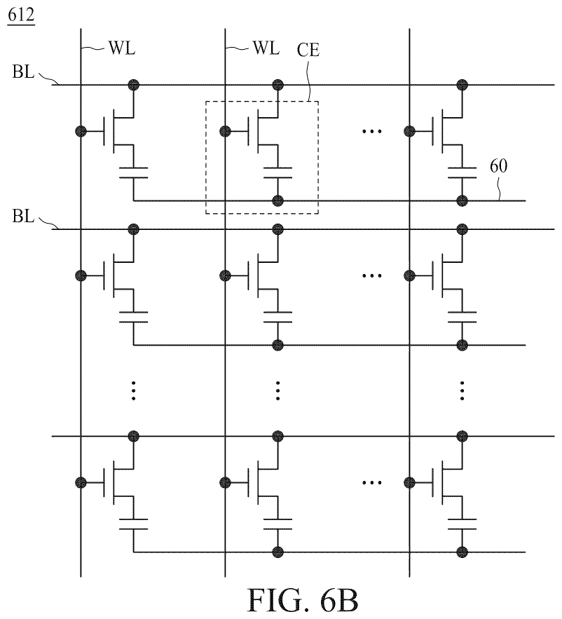

FIG. 6A is a top view of a memory block 600 of the memory chip 502 of FIG. 5, according to some embodiments of the present disclosure. Each memory chip 502 includes one or more memory blocks 600. The memory block 600 includes a plurality of MATs 610. The MAT 610 includes a memory array 612 (e.g., a DRAM memory array), a sensing circuit 614, and a driving circuit 616, where the memory array 612 is coupled to the sensing circuit 614 and the driving circuit 616. FIG. 6B is a circuit schematic of the memory array 612, according to some embodiments of the present disclosure. The memory array 612 includes a plurality of word lines WL, a plurality of bit lines BL, and a plurality of memory cells CE disposed at intersections of the word lines WL and the bit lines BL. The memory cells CE may be DRAM memory cells. For example, each memory cell CE of the memory array 612 may be a one transistor-one capacitor (1T1C) memory cell. A first terminal of each capacitor in the memory cell CE may be coupled to the transistor in the same memory cell CE. Second terminals of capacitors of a group of memory cells CE, such as, but not limited to, those arranged in a column or a row, may be coupled to a common electrode 60.

Reference is made to FIG. 6A again. From the top view of the memory block 600 of the memory chip 502, the sensing circuit 614 is disposed in a first region R1; the memory array 612 is disposed in a second region R2; and the driving circuit 616 is disposed in a third region R3. The second region R2 is adjacent to the first region R1 and the third region R3. The sensing circuit 614 can amplify the small voltage differences on the bit lines BL of the memory array 612 during a read operation. The driving circuit 616 can provide the necessary current and voltage levels to selectively activate one of the word lines WL of the memory array 612 to select the specific row of memory cells CE.

The MAT 610 further includes a plurality of first pads 620, a plurality of second pads 630, and a plurality of third pads 640. The first pads 620 are disposed in the first region R1, and are disposed over the sensing circuit 614. The first pads 620 may be electrically coupled to the sensing circuit 614 through traces extending substantially vertically. The second pads 630 are disposed in the second region R2, and are disposed over the memory array 612. The second pads 630 may be electrically coupled to the memory array 612 through traces extending substantially vertically. The third pads 640 are disposed in the third region R3, and are disposed over the driving circuit 616. The third pads 640 may be electrically coupled to the driving circuit 616 through traces extending substantially vertically. The first pads 620, the second pads 630, and the third pads 640 are electrically connected to the logic chip 503. Accordingly, the logic chip 503 can access the MAT 610 through the first pads 620, the second pads 630, and the third pads 640.

In the present embodiment, the first pads 620, the second pads 630, and the third pads 640 may be arranged in a staggered manner. For example, the first pads 620 form a plurality of rows extending in the direction X and a plurality of columns extending in the direction Y, where the direction X and the direction Y are perpendicular to each other. Each row of the first pads 620 is misalignment to the adjacent row in the direction Y. Each column of the first pads 620 is misalignment to the adjacent column in the direction X. In some embodiments, the pitch between two adjacent first pads 620 is less than 2 μm. The pitch may be the distance measured from the center of one first pad 620 to another first pad 620. The above descriptions regarding the first pads 620 can be applied to the second pads 630 and the third pads 640. The arrangements of the first pads 620, the second pads 630, and the third pads 640 in FIG. 6A are merely examples and are not intended to limit the scope of the present disclosure. In some embodiments, the first pads 620 may be arranged as a rectangular array, and the same can be applied to the second pads 630 and the third pads 640.

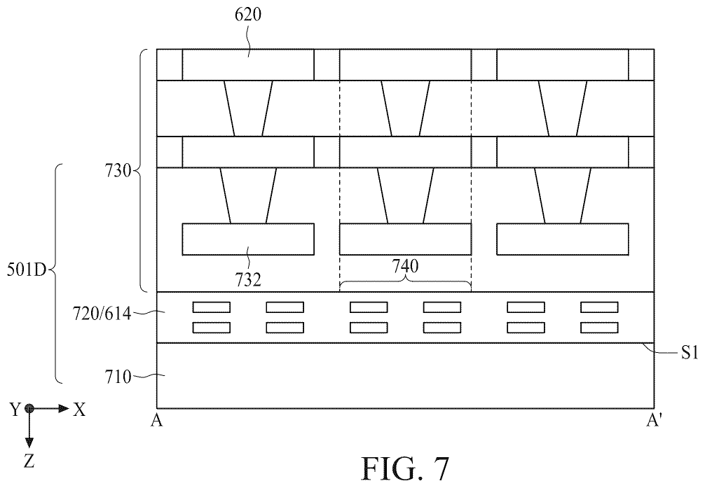

FIG. 7 is a side view of the MAT 610 along the line AA′ of FIG. 6, according to some embodiments of the present disclosure. Referring to FIG. 5 and FIG. 7, it is noted that the wafer 501D is flipped over for the connection with the wafer 501L. In this flipped configuration, a top surface S1 of a substrate 710 of the wafer 501D faces toward the wafer 501L. However, regardless of whether the wafer 501D is flipped or not, the substrate 710 is considered the bottom-most layer of the wafer 501D, and other layers of the wafer 501D can be formed over the top surface S1 of the substrate 710. For example, a device layer 720 and a dielectric layer 730 are formed sequentially over the top surface S1 of the substrate 710. Thus, the term “over” as used herein refers to the relative position of layers formed on or above the top surface S1 of the substrate 710, independent of the orientation of the wafer 501D during bonding.

The device layer 720 may include a single layer or multiple layers with different materials. These materials can include semiconductors, insulators, conductors, or combinations thereof. For example, the device layer 720 may include active electronic devices (e.g., transistors), passive electronic devices (e.g., resistors, capacitors, and inductors), and conductive lines connected between these devices. The sensing circuit 614 may be formed in the device layer 720. The dielectric layer 730 may include a single layer or multiple layers with different materials. A plurality of data line segments 732 of the sensing circuit 614 are formed in the dielectric layer 730. The data line segments 732 can transmit the output of the sensing circuit 614.

The first pads 620, which are above the data line segments 732 of the sensing circuit 614, are formed in the dielectric layer 730 and exposed by the dielectric layer 730. Each data line segment 732 may be electrically connected to a corresponding first pad 620, through one or more vias, contacts, conductive lines, or a combination thereof stacked vertically. The number of layers of elements between the data line segment 732 and the first pad 620 is merely an example and is not intended to limit the scope of the present disclosure. The first pads 620 may be configured to provide the output of the sensing circuit 614 to the secondary sensing circuit 509 of the logic chip 503. Each first pad 620 has a vertical projection 740 on a top surface of the device layer 720. The vertical projections 740 overlap with the sensing circuit 614. In other words, when viewed form the top of the MAT 610 (i.e., viewed in the direction Z), the first pads 620 overlap with the sensing circuit 614, where the direction X, direction Y, and the direction Z are perpendicular to each other.

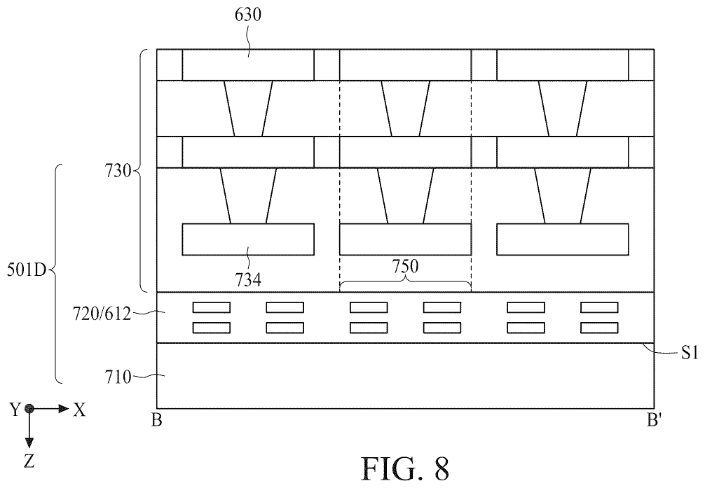

FIG. 8 is a side view of the MAT 610 along the line BB′ of FIG. 6, according to some embodiments of the present disclosure. The memory array 612 is formed in the device layer 720. A plurality of power lines 734 are formed in the dielectric layer 730. The power lines 734 are electrically connected to the memory array 612 to provide voltages necessary for the operations of the memory array 612. In some embodiments, the power lines 734 include one or more common electrodes 60 (depicted in FIG. 6B) connected to the plurality of capacitors of the memory cells CE. The power lines 734 can be configured to provide a supply voltage (e.g., the highest voltage in the memory array 612), the ground voltage, or any suitable capacitor plate potential to the plurality of capacitors.

The second pads 630, which are above the power lines 734, are formed in the dielectric layer 730 and exposed by the dielectric layer 730. Each power line 734 may be electrically connected to a corresponding second pad 630, through one or more layers of vias, contacts, conductive lines, or a combination thereof stacked vertically. The number of layers of elements between the power line 734 and the second pad 630 is merely an example and is not intended to limit the scope of the present disclosure. The second pads 630 may be configured to receive the voltages necessary for the operations of the memory array 612 from the driver 508 of the logic chip 503. Each second pad 630 has a vertical projection 750 on the top surface of the device layer 720. The vertical projections 750 overlap with the memory array 612. In other words, when viewed form the top of the MAT 610 (i.e., viewed in the direction Z), the second pads 630 overlap with the memory array 612.

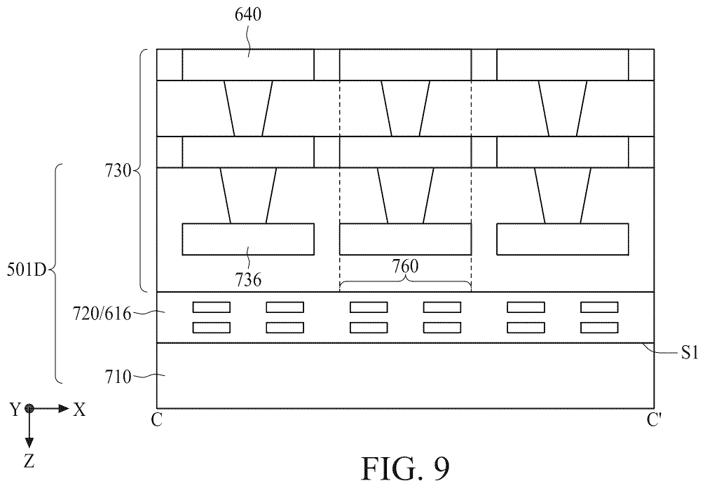

FIG. 9 is a side view of the MAT 610 along the line CC′ of FIG. 6, according to some embodiments of the present disclosure. The driving circuit 616 is formed in the device layer 720. A plurality of driving lines 736 are formed in the dielectric layer 730. The driving lines 736 are electrically connected to the driving circuit 616 to provide voltages necessary for the activation of the word lines WL of the MAT 610.

The third pads 640, which are above the driving lines 736, are formed in the dielectric layer 730 and exposed by the dielectric layer 730. Each driving line 736 may be electrically connected to a corresponding third pad 640, through one or more layers of vias, contacts, conductive lines, or a combination thereof stacked vertically. The number of layers of elements between the driving line 736 and the third pad 640 is merely an example and is not intended to limit the scope of the present disclosure. The third pads 640 may be configured to receive a global enable signal GE (depicted in FIG. 5) from the driver 508 of the logic chip 503, and transmit the global enable signal GE to the driving circuit 616 to activate the driving circuit 616. The third pads 640 may also be configured to receive a local row enable signal RE (depicted in FIG. 5), and transmit the local row enable signal to the driving circuit 616. The driving circuit 616 may activate a specific word line WL of the memory array 612 according to the local row enable signal. In some embodiments, the global enable signal GE and the local row enable signal may be one-hot signals. Each third pad 640 has a vertical projection 760 on the top surface of the device layer 720. The vertical projections 760 overlap with the driving circuit 616. In other words, when viewed form the top of the MAT 610 (i.e., viewed in the direction Z), the third pads 640 overlap with the driving circuit 616.

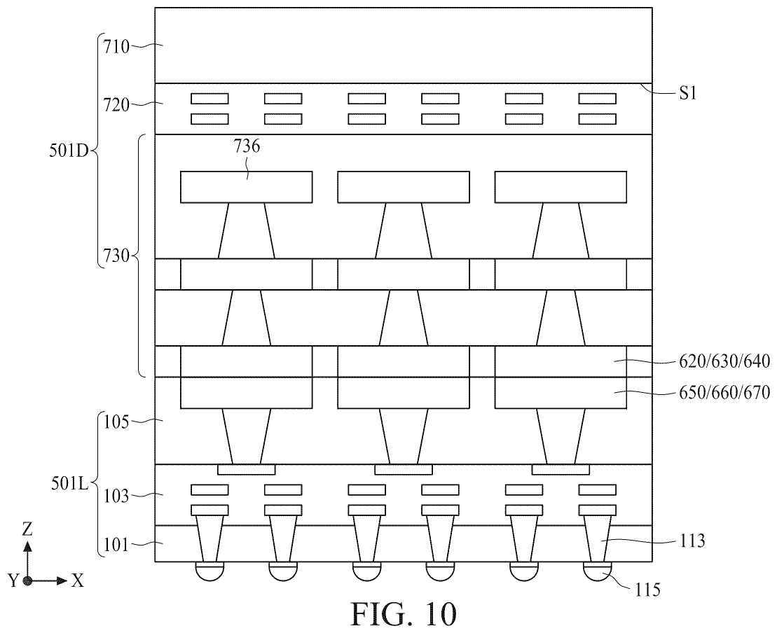

FIG. 10 is a side view of the semiconductor device 500 according to some embodiments of the present disclosure. The wafer 501D is flipped over to connect to the wafer 501L in a face-to-face manner. That is, the substrate 710 of the wafer 501D is distal to the wafer 501L, and the top surface S1 of the substrate 710 of the wafer 501D faces toward the wafer 501L. The wafer 501L includes a substrate 101, a device layer 103, and a dielectric layer 105. The device layer 103 may include a single layer or multiple layers with different materials. These materials can include semiconductors, insulators, conductors, or combinations thereof. For example, the device layer 103 may include active electronic devices (e.g., transistors), passive electronic devices (e.g., resistors, capacitors, and inductors), and conductive lines connected between these devices. The logic chips 503 may be formed in the device layer 103. The dielectric layer 105 is formed over the device layer 103. The dielectric layer 730 may include a single layer or multiple layers with different materials.

The wafer 501L further includes a plurality of fourth pads 650, a plurality of fifth pads 660, and a plurality of sixth pads 670, which are formed in the dielectric layer 105 and exposed by the dielectric layer 105. The fourth pads 650, the fifth pads 660, and the sixth pads 670 of the wafer 501L may be directly connected to the first pads 620, the second pads 630, and the third pads 640 of the wafer 501D, respectively. The fourth pads 650, the fifth pads 660, and the sixth pads 670 may be part of the logic chips 503, and are electrically connected to the device layer 103. The wafer 501L and the wafer 501D may have a configuration of face-to-face stacking wafer-to-wafer bonding. The bonding of the wafer 501L and the wafer 501D may be performed through hybrid bonding process. For example, the fourth pads 650, the fifth pads 660, and the sixth pads 670 of the wafer 501L are aligned with the first pads 620, the second pads 630, and the third pads 640 of the wafer 501D, respectively. Then, the pads form direct metallic bonds and the dielectric layers form covalent bonds. An annealing process may be performed subsequently, which helps reduce voids and improves the mechanical and electrical integrity of the hybrid bonding structure.

The wafer 501L further includes a plurality of through silicon vias (TSVs) 113. The TSVs 113 penetrate the substrate 101 of the wafer 501L to electrically connect the device layer 103 to a plurality of bumps 115. Therefore, the logic chip 503 may include the TSVs 113. Before forming the TSVs 113, a chemical mechanical planarization (CMP) process may be performed to the substrate 101 of the wafer 501L to reduce the thickness of the substrate 101 in the direction Z. Therefore, the thickness of the substrate 101 in the direction Z may be smaller than that of the substrate 710. It is noted that the memory chip 502 and the wafer 501D in the embodiment of FIG. 10 may be free from the TSVs.

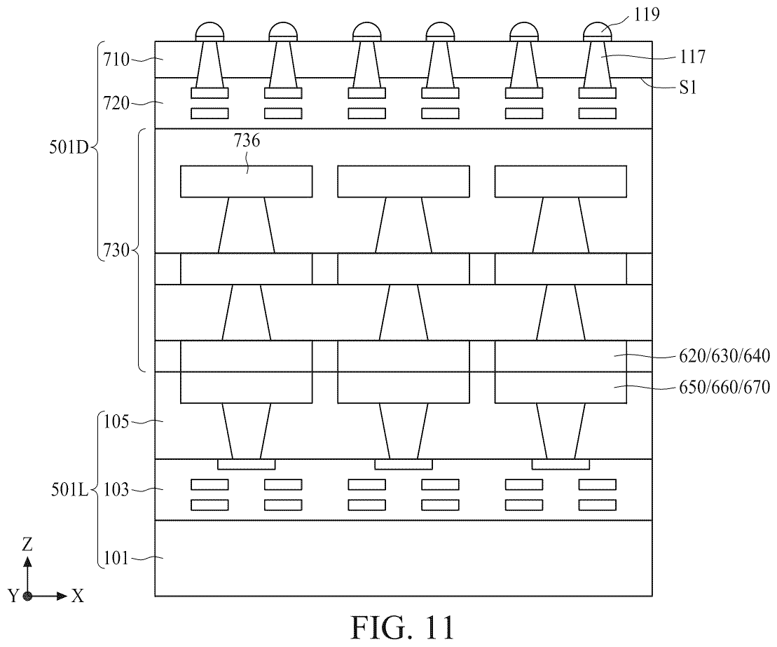

FIG. 11 is a side view of the semiconductor device 500 according to some embodiments of the present disclosure. The embodiments of FIG. 11 is similar to the embodiment of FIG. 10; therefore, only the differences are described below. The wafer 501D further includes a plurality of TSVs 117. The TSVs 117 penetrate the substrate 710 of the wafer 501D to electrically connect the device layer 720 to a plurality of bumps 119. Therefore, the memory chip 502 may include the TSVs 117. Before forming the TSVs 117, a CMP process may be performed to the substrate 710 of the wafer 501D to reduce the thickness of the substrate 710 in the direction Z. Therefore, the thickness of the substrate 710 in the direction Z may be smaller than that of the substrate 101. It is noted that the logic chip 503 and the wafer 501L in the embodiment of FIG. 11 may be free from the TSVs.

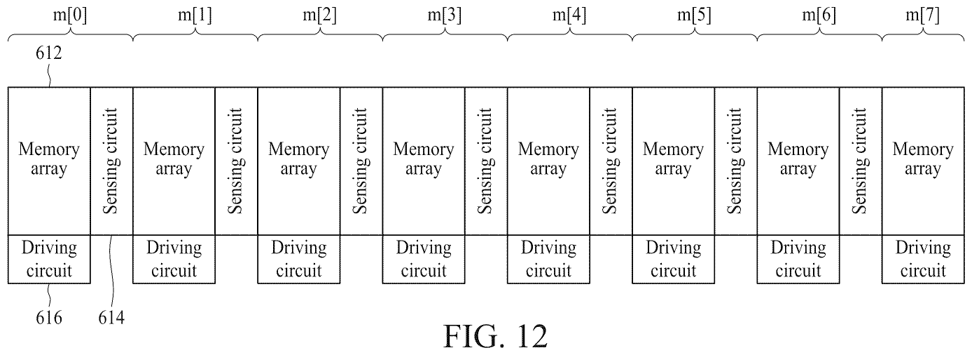

FIG. 12 is a functional block diagram illustrating a row formed by MATs m[0] to m[7], according to some embodiments of the present disclosure. Each of the MATs m[0] to m[6] is similar to the MAT 610 of FIG. 6. The MAT m[7] is also similar to the MAT 610 of FIG. 6, except that the MAT m[7] may be free from the sensing circuit 614 and the first pads 620. Accordingly, the row formed by the MATs m[0] to m[7] may be one of the rows of the memory block 600 of FIG. 6. The number of MATs in the row is merely an example and is not intended to limit the scope of the present disclosure. Each sensing circuit 614 is disposed between two neighboring memory arrays 612, and shared by the two neighboring memory arrays 612. In other words, each first region R1 is disposed between two neighboring second regions R2. In some embodiments, when one of the MATs m[0] to m[7] is activated, neighboring MATs sharing the sensing circuit 614 with the activated MAT are inactive. For example, when the MAT m[1] is activated, the MATs m[0] and m[2] are inactive.

With respect to a row of a memory array 612 disposed between two sensing circuits 614, a part of memory cells of the row is coupled to one of the sensing circuits 614, while another part of the memory cells of the row is coupled to another sensing circuit 614. For example, a part of the memory cells of a row of the MAT m[1] is coupled to the sensing circuit 614 between the MAT m[1] and the MAT m[0], while another part of the memory cells of the row of the MAT m[1] is coupled to the sensing circuit 614 between the MAT m[1] and the MAT m[2]. In other words, the sensing circuit 614 can access data associated with the two neighboring MATs. Accordingly, by sharing the sensing circuits 614, the overall circuit area is reduced.

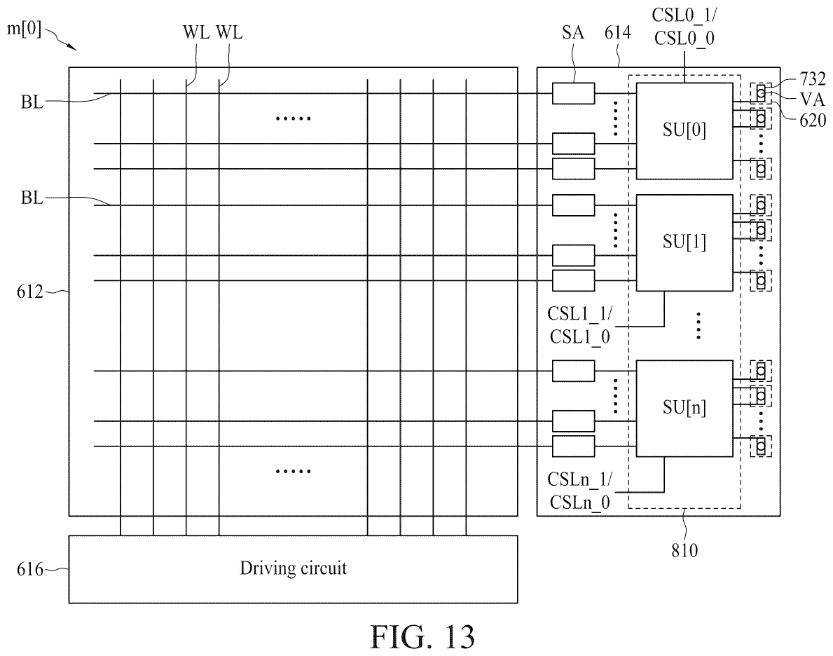

FIG. 13 is a circuit schematic of the MAT m[0] according to some embodiments of the present disclosure. The MATs m[1] to m[6] of FIG. 12 may have circuit configurations similar to those illustrated in FIG. 13. The MAT m[0] includes the plurality of word lines WL and the plurality of bit lines BL perpendicular to the word lines WL. The MAT m[0] further includes the plurality of memory cells CE (not shown in FIG. 13) disposed at intersections of the word lines WL and the bit lines BL. The word lines WL are coupled to the driving circuit 616, while the bit lines BL are coupled to the sensing circuit 614.

The sensing circuit 614 includes the plurality of data line segments 732, a plurality of sensing amplifiers SA, and a column selection circuit 810. Therefore, from the top view of the memory chip 502, the data line segments 732, the sensing amplifiers SA, and the column selection circuit 810 are disposed in the first region R1. The column selection circuit 810 is configured to selectively couple the sensing amplifiers SA to the plurality of data line segments 732, according to a plurality of pairs of column selection signals CSL0_0/CSL0_1, CSL1_0/CSL1_1, . . . , CSLn_0/CSLn_1. The outputs of the sensing amplifiers SA are therefore selectively transmitted to the first pads 620. The column selection circuit 810 includes a plurality of column selection units SU[0] to SU[n], where n is a positive integer. The column selection units SU[0] is controlled by the column selection signal CSL0_0 and CSL0_1; column selection units SU[1] is controlled by the column selection signal CSL1_0 and CSL1_1, and so on. The pairs of column selection signals CSL0_0/CSL0_1, CSL1_0/CSL1_1, . . . , CSLn_0/CSLn_1 may be the same or different from one another. For example, when the pairs of the column selection signals CSL0_0/CSL0_1, CSL1_0/CSL1_1, . . . , CSLn_0/CSLn_1 are the same, the column selection signals CSL0_0, CSL1_0, . . . , CSLn_0 may be activated simultaneously, and the column selection signals CSL0_1, CSL1_1, . . . , CSLn_1 may be activated simultaneously. In some embodiments, the column selection signals in each pair may be different. For example, the column selection signals CSL0_0 and CSL0_1 may be opposite to each other.

The data line segments 732 are coupled with the first pads 620, respectively, through a plurality of vias VA. The vias VA represent the one or more vias disposed between a pair of data line segment 732 and first pad 620 that are discussed with respect to FIG. 7. In some embodiments, the number of bits (i.e., memory cells CE) on each word line WL is less than 688; that is, the number of bit lines BL is less than 688. When there are k bits per word line WL (i.e., k bit lines BL), the MAT m[0] may include

$$\frac{k}{2} + 1$$

data line segments 732, where k is a positive integer or k/2 is a positive integer.

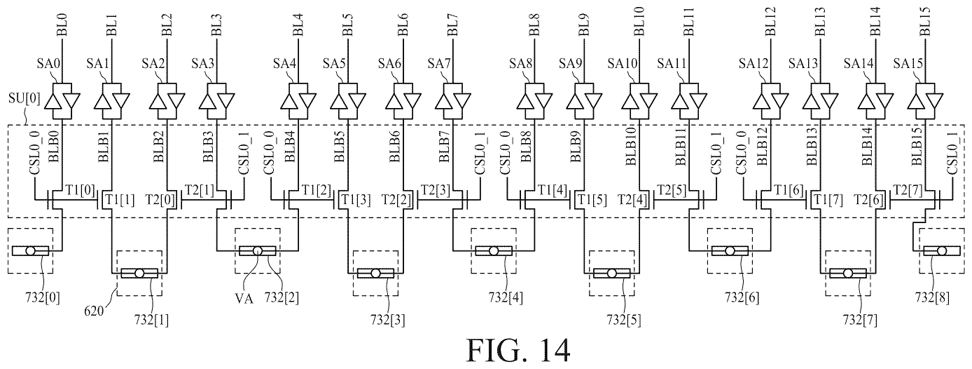

FIG. 14 is a circuit schematic of the column selection unit SU[0] according to some embodiments of the present disclosure. Other column selection units SU[1] to SU[n] in FIG. 13 may have circuit configurations similar to those illustrated in FIG. 14. The column selection unit SU[0] is coupled to the plurality of sensing amplifiers SA (hereinafter referred to as “sensing amplifiers SA0 to SA15”). The column selection unit SU[0] includes a plurality of first transistors T1[0] to T1[7] and a plurality of second transistors T2[0] to T2[7]. The numbers of elements in FIG. 14 are merely examples and are not intended to limit the scope of the present disclosure.

The first transistors T1[0] to T1[7] are controlled by the column selection signal CSL0_0. The second transistors T2[0] to T2[7] are controlled by the column selection signal CSL0_1. In some embodiments, the first transistors T1[0] to T1[7] and the second transistors T2[0] to T2[7] are N-type transistors. A first terminal of each of the first transistors T1[0] to T1[7] are coupled to a corresponding sensing amplifier SA through a corresponding bit line BL, and a second terminal of each of the first transistors T1[0] to T1[7] are coupled to a corresponding data line segment 732; the same can be applied to the second transistors T2[0] to T2[7]. In other words, the first transistors T1[0] to T1[7] are coupled to a set of sensing amplifiers SA0, SA1, SA4, SA5, SA8, SA9, SA12, and SA13, while the second transistors T2[0] to T2[7] are coupled to another set of sensing amplifiers SA2, SA3, SA6, SA7, SA10, SA11, SA14, and SA15. In the present embodiment, each data line segment 732 are coupled to no more than two sensing amplifiers SA; however, the present disclosure is not limited thereto.

As shown in FIG. 14, the data line segments 732 (hereinafter referred to as “data line segments 732[0] to 732[8]”) are arranged in a horizontal direction in first sequence. The horizontal direction may be in parallel to the plane formed by the direction X and the direction Y of FIG. 6A; however, the present disclosure is not limited thereto. That is, the data line segments 732[0] to 732[8] are arranged sequentially from left to right. The first transistors T1[0] to T1[7] are arranged in the horizontal direction in second sequence. That is, the first transistors T1[0] to T1[7] are arranged sequentially from left to right. The second transistors T2[0] to T2[7] are arranged in the horizontal direction in third sequence. That is, the second transistors T2[0] to T2[7] are arranged sequentially from left to right. The foremost data line segment 732[0] in the first sequence is coupled to the foremost first transistor T1[0] in the second sequence, and is not coupled to any second transistor. The last data line segment 732[8] in the first sequence is coupled to the last second transistor 732[8] in the third sequence, and is not coupled to any first transistor. Each of the remaining data line segments 732[1] to 732[7] are coupled to a corresponding first transistor and a corresponding second transistor. For example, the data line segment 732[1] is coupled to the first transistor T1[1] and the second transistor T2[0].

The first transistors T1[0] to T1[7] and the second transistors T2[0] to T2[7] are arranged alternately. Transistor groups each including two first transistors are arranged alternately with transistor groups each including two second transistors. For example, the transistor group including the second transistors T2[0] and T2[1] are disposed between the transistor group including the first transistors T1[0] and T1[1] and the transistor group including the first transistors T1[2] and T1[3]. In addition, the data line segments 732[0] to 732[8] are arranged in the staggered manner. For example, the data line segments 732[0] to 732[8] are arranged in the horizontal direction, but are misaligned with each other when viewed in the horizontal direction. The two neighboring data line segments have different distance to the column selection circuit 810 in the vertical direction. That is, the data line segments 732[0] to 732[8] are configured to have a staggered distribution pattern along the horizontal direction. However, the present disclosure is not limited thereto. In some embodiments, the data line segments 732[0] to 732[8] may be aligned with each other in the horizontal direction. That is, the data line segments 732[0] to 732[8] are configured to have a straight line pattern along the horizontal direction.

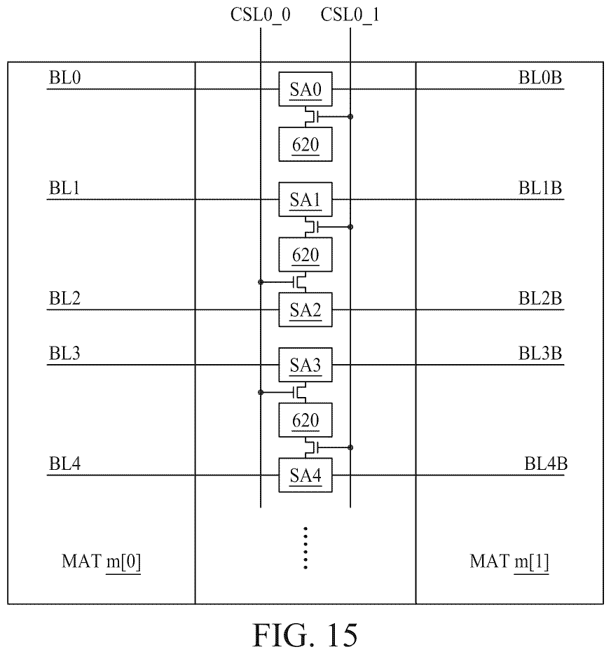

FIG. 15 is a circuit schematic illustrating the connection configuration of the column selection unit SU[0] between the MAT m[0] and the MAT m[1], according to some embodiments of the presents disclosure. Reference is made to FIG. 14 and FIG. 15. In some embodiments, the sensing amplifiers SA0 to SA15 may be of the latch-type configuration, each including a first input terminal and a second input terminal. The first input terminals of the sensing amplifiers SA0 to SA15 are coupled to the bit lines BL of the MAT m[0](denoted as “bit lines BL0 to BL15”), respectively. The second input terminal of the sensing amplifiers SA0 to SA15 are coupled to the bit lines BL of the MAT m[1](denoted as “bit lines BLB0 to BLB15”), respectively.

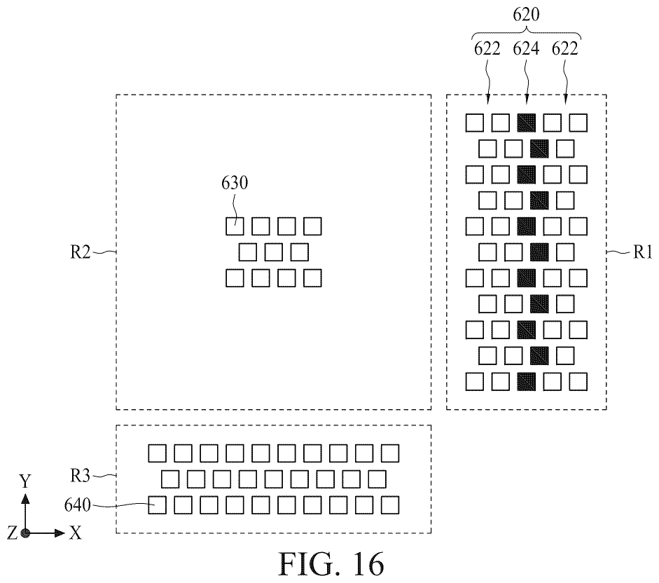

FIG. 16 is a top view of the MAT m[0] according to some embodiments of the present disclosure. Similar to those described with reference to FIG. 6, the MAT m[0] includes the first pads 620 within the first region R1, the second pads 630 within the second region R2, and the third pads 640 within the third region R3. The difference is that the first pads 620 of the MAT m[0] includes a plurality of first specific pads 622 (i.e., the white squares depicted in FIG. 16) and a plurality of second specific pads 624 (i.e., the black squares depicted in FIG. 16). The second specific pads 624 are coupled with the column selection circuit 810, and are configured to receive the column selection signals CSL0_0/CSL0_1, CSL1_0/CSL1_1, . . . , CSLn_0/CSLn_1 from the logic chip 503. The second specific pads 624 are disposed in the first region R1, and are disposed over the sensing circuit 614. Similar to those described with reference to FIG. 7, the vertical projections of the second specific pads 624 projected onto the top surface of the device layer 720 overlap with the sensing circuit 614. The second specific pads 624 are interposed between the first specific pads 622. When viewed in the direction X, the first specific pads 622 and the second specific pads 624 are disposed in a side-by-side manner. For example, each second specific pads 624 is disposed between two first specific pads 622. However, the present disclosure is not limited thereto. In some embodiments, the second specific pads 624 are disposed adjacent to an edge of the array formed by the first pads 620, so that only one side of each second specific pad 624 is adjacent to the first specific pad 622.

Table 1 shows a comparison of signal latency between the memory chip 110 of FIG. 1 and the memory chip 502 of FIG. 5.

TABLE 1

| | Memory chip | Memory chip |
|---|---|---|
| Source of signal latency | 110 | 502 |
| Decoder and global word line RC | about 2 ns | Removed |
| Local driving circuit and local word line RC | about 8 ns | about 2 ns |
| | (long word line) | (short word line) |
| Local sensing circuit | about 10 ns | about 1 ns |
| | (heavy load) | (small load) |
| Data line | about 2 ns | Removed |
| Secondary sensing circuit | about 2 ns | Removed |
| Output wiring | about 2 ns | about 1 ns |

Compared with the memory chip 110, the memory chip 502 reduces the signal latency by removing the secondary sensing circuit, the decoder, the driver, and the global word lines connected between the driver and the MATs. In addition, as the signals for activating the local word lines WL in the MAT 610 can be received from the third pads 640 above the local driving circuit 616, the local driving circuit 616 can have compact configuration. Therefore, the length of the local word lines WL can be reduced, thereby reducing the RC delay on the local word lines WL.

In the memory chip 110 of FIG. 1, lots of sensing amplifiers share a long global data line. In comparison, the memory chip 502 replaces the global data line with the data line segments 732 each shared by no more than two sensing amplifiers SA, thereby removing the signal latency caused by the global data line and increasing the output bandwidth. In addition, the short wiring length from the sensing circuit 614 to the first pads 620 reduces the output loading of the sensing circuit 614, thereby reducing the signal latency caused by the sensing circuit 614 and the output wiring.

According to Table 1, the signal latency (i.e., access time) of the memory chip 502 is less than 5 ns. Moreover, based on the circuit simulation, the memory chip 502 have a power consumption of approximately 0.03 pJ/bit and a bandwidth comparable to the SRAM. Accordingly, the semiconductor device 500 and the memory chip 502, which may include DRAM cells, are suitable for high speed computing. For example, the memory chip 502 is suitable for the use as a replacement for SRAM in implementing high-density Level 1 through Level 3 cache.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory chip, comprising:
a substrate; and
a plurality of memory array tiles (MATs), disposed over the substrate, wherein at least one MAT of the plurality of MATs comprises:
a sensing circuit, wherein from a top view of the memory chip, the sensing circuit is disposed in a first region;
a memory array, wherein from the top view of the memory chip, the memory array is disposed in a second region adjacent to the first region, and is electrically coupled to the sensing circuit; and
a plurality of first pads, wherein from the top view of the memory chip, the plurality of first pads are disposed in the first region, wherein the plurality of first pads are disposed over the sensing circuit, wherein the plurality of first pads are electrically coupled to the sensing circuit, and are configured to provide output of the sensing circuit.

2. The memory chip of claim 1, wherein the memory array comprises a plurality of power lines, wherein the at least one MAT further comprises:
a plurality of second pads, wherein from the top view of the memory chip, the plurality of second pads are disposed in the second region, wherein the plurality of second pads are disposed over the memory array, wherein the plurality of second pads are electrically coupled to the plurality of power lines.

3. The memory chip of claim 2, wherein the memory array comprises a plurality of capacitors,
wherein the plurality of power lines are electrically connected to the plurality of capacitors,
wherein each of the plurality of power lines is configured to provide a supply voltage, a ground voltage, or a capacitor plate potential to the plurality of capacitors.

4. The memory chip of claim 1, wherein the at least one MAT further comprises:
a driving circuit, wherein from the top view of the memory chip, the driving circuit is located in a third region adjacent to the second region, wherein the driving circuit is configured to selectively activate one of a plurality of word lines of the memory array; and
a plurality of third pads, wherein from the top view of the memory chip, the plurality of third pads are located in the third region, wherein the plurality of third pads are disposed over the driving circuit, wherein the plurality of third pads are electrically coupled to the driving circuit.

5. The memory chip of claim 1, wherein the sensing circuit comprises:
a plurality of data line segments, wherein from the top view of the memory chip, the plurality of data line segments is disposed in the first region, the data line segments are coupled with the plurality of first pads;
a plurality of sensing amplifiers; and
a column selection circuit, configured to selectively couple the plurality of sensing amplifiers to the plurality of data line segments, according to a plurality of pairs of column selection signals, wherein column selection signals in each pair of the plurality of pairs of column selection signals are the same or different from one another.

6. The memory chip of claim 5, wherein the plurality of first pads comprises a plurality of first specific pads electrically connected to the data line segments, and a plurality of second specific pads electrically connected to the column selection circuit.

7. The memory chip of claim 6, wherein, from a top view of the memory chip, the plurality of second specific pads is interposed between the plurality of first specific pads.

8. The memory chip of claim 6, wherein, from a top view of the memory chip, the plurality of first specific pads and the plurality of second specific pads are disposed side-by-side.

9. The memory chip of claim 5, wherein, from a top view of the memory chip, the plurality of data line segments are configured to have a staggered distribution pattern along a specific direction.

10. The memory chip of claim 5, wherein, from a top view of the memory chip, the plurality of data line segments are configured to have a straight line pattern along a specific direction.

11. The memory chip of claim 1, wherein one of the plurality of MATs is free from the sensing circuit and the plurality of first pads,
wherein each first region is located between two neighboring second regions, and each sensing circuit is shared by two neighboring memory arrays.

12. The memory chip of claim 1, wherein the plurality of first pads of the at least one MAT are arranged to electrically couple to a plurality of fourth pads of a logic chip through a hybrid bonding structure.

13. A semiconductor device, comprising:
a memory chip, comprising a substrate and a plurality of memory array tiles (MATs) disposed over the substrate of the memory chip, wherein at least one MAT of the plurality of MATs comprises a sensing circuit, a memory array electrically coupled to the sensing circuit, and a plurality of first pads electrically coupled to the sensing circuit and configured to provide output of the sensing circuit; and
a logic chip, comprising:
a substrate; and
a plurality of fourth pads, wherein from a side view of the logic chip, the plurality of fourth pads are disposed over the substrate of the logic chip,
wherein the plurality of first pads of the at least one MAT are directly coupled to the plurality of fourth pads of the logic chip.

14. The semiconductor device of claim 13, wherein the memory array comprises a plurality of power lines, wherein the at least one MAT further comprises:
a plurality of second pads, electrically coupled to the plurality of power lines;
wherein the logic chip further comprises a plurality of fifth pads disposed over the substrate of the logic chip, and the plurality of fifth pads of the logic chip are directly coupled to the plurality of second pads of the at least one MAT.

15. The semiconductor device of claim 14, wherein the memory array comprises a plurality of capacitors, and the plurality of power lines are configured to provide a supply voltage, a ground voltage, or a capacitor plate potential to the plurality of capacitors through the plurality of second pads and the plurality of fifth pads.

16. The semiconductor device of claim 13, wherein the at least one MAT further comprises:
a driving circuit, configured to selectively activate one of a plurality of word lines of the memory array; and
a plurality of third pads, electrically coupled to the driving circuit;
wherein the plurality of third pads are directly coupled to the plurality of fourth pads of the logic chip.

17. The semiconductor device of claim 16, wherein the logic chip is configured to:
provide a global enable signal to the driving circuit through the plurality of third pads and the plurality of fourth pads to activate the driving circuit, and
provide a local row enable signal to the driving circuit through the plurality of third pads and the plurality of fourth pads, wherein the driving circuit is configured to activate the one of the plurality of word lines of the memory array according to the local row enable signal.

18. The semiconductor device of claim 13, wherein the pads on the memory chip and the pads on the logic chip are coupled to each other through a hybrid bonding structure.

19. The semiconductor device of claim 13, wherein the logic chip further comprises a device layer electrically connected to the plurality of fourth pads, wherein from the side view of the logic chip, the device layer of the logic chip is disposed over the substrate of the logic chip, wherein the semiconductor device further comprises:
a plurality of through silicon vias, penetrating the substrate of the logic chip to electrically connect to the device layer of the logic chip,
wherein the memory chip is free from through silicon vias.

20. The semiconductor device of claim 13, wherein the memory chip further comprises a device layer electrically connected to the plurality of first pads, wherein from the side view of the memory chip, the device layer of the memory chip is disposed over the substrate of the memory chip, wherein the plurality of MATs are disposed in the device layer, wherein the semiconductor device further comprises:
a plurality of through silicon vias, penetrating the substrate of the memory chip to electrically connect to the device layer of the memory chip,
wherein the logic chip is free from through silicon vias.
